(19) United States
(12) Patent Application Publication
(10) Pub. No.: US 2026/0155830 A1
(43) Pub. Date: Jun. 4, 2026

(54) SIGNAL PROCESSING CIRCUIT

(71) Applicant: Rohde & Schwarz GmbH & Co. KG, Munich (DE)

(72) Inventors: Matthias GOETZ, Munich (DE); Marcus BUECHE, Olching (DE)

(21) Appl. No.: 18/963,957

(22) Filed: Nov. 29, 2024

(51) Int. Cl. H03M 1/10

(52) U.S. Cl. CPC H03M 1/1023

(57) ABSTRACT

The present disclosure relates to a signal processing circuit, comprising: at least one divider configured to receive an input clock signal with a first frequency and to generate an output clock signal with a second frequency which is a fraction of the first frequency; a reference signal unit configured to generate or to receive a phase reference signal; and at least one phase detector configured to detect a phase offset between the output clock signal and the phase reference signal; wherein the at least one divider is configured to shift a phase of its output clock signal in order to adapt the phase offset between its output clock signal and the phase reference signal.

### TECHNICAL FIELD

The present disclosure relates to a signal processing circuit for synchronizing electrical signals, for instance in a converter system.

### BACKGROUND ART

Analog-to-digital converters (ADCs) are critical components in modern electronics which convert analog signals into digital data that can be processed by digital systems. They are widely used in various applications such as audio and video processing, communication systems, and instrumentation. The performance of an ADC is often characterized by its sampling rate.

For some applications, a single ADC may not be sufficient to meet the required sampling rates. To overcome this limitation, a technique called interleaving can be used. Interleaving involves using two or more ADCs with a defined clocking relationship to simultaneously sample an input signal. Thus, by interleaving ADCs the overall sampling rate can be effectively increased.

A large ADC system can comprise several channels with groups of interleaved ADCs.

Thereby, the ADCs across the various channels should be synchronized to each other, which is difficult to realize.

### SUMMARY

Thus, there is a need to provide an improved signal processing circuit for synchronizing of electrical signals and devices.

This is achieved by the embodiments provided in the enclosed independent claims. Advantageous implementations of the present disclosure are further defined in the dependent claims.

According to a first aspect, the present disclosure relates to a signal processing circuit, comprising: at least one divider configured to receive an input clock signal with a first frequency and to generate an output clock signal with a second frequency which is a fraction of the first frequency; a reference signal unit configured to generate or to receive a phase reference signal; and at least one phase detector configured to detect a phase offset between the output clock signal and the phase reference signal; wherein the at least one divider is configured to shift a phase of its output clock signal in order to adapt the phase offset between its output clock signal and the phase reference signal.

By means of the signal processing circuit, different instances, for example ADCs and groups of sub-samplers, of a large converter system can be synchronized.

For example, the second frequency of the output clock signal corresponds to the first frequency divided by a division ratio (N).

In an implementation form, the at least one divider is configured to shift the phase of its output clock signal by at least one period or half-period of the input clock signal.

In an implementation form, the at least one divider is configured to minimize the phase offset between its output clock signal and the phase reference signal and/or to set the phase offset between its output clock signal and the phase reference signal to be in a determined range.

In an implementation form, the at least one divider comprises a programmable polyphase unit which is configured to shift the phase of its output clock signal in order to adapt the phase offset between its output clock signal and the phase reference signal.

In an example, the programmable polyphaser unit is a slip gate.

In an implementation form, the reference signal unit comprises a reference clock configured to generate the phase reference signal based on the input clock signal.

For example, the phase reference signal is derived from a sampling clock by division.

In an implementation form, the phase reference signal is an external signal which is received by the reference signal unit.

In an implementation form, the signal processing circuit comprises an input for receiving a synchronization pulse signal which is synchronous to the phase reference signal.

According to a second aspect, the present disclosure relates to an analog-to-digital converter system, comprising: the signal processing circuit according to the first aspect of the disclosure, and an analog-to-digital converter circuit configured to convert an analog input signal to a digital output signal.

In an implementation form, the analog-to-digital converter system further comprises: at least one group of sub-samplers which are configured to sample the analog input signal based on the output clock signal provided by the divider. The sampled analog input signal can then be converted by the ADC to the digital output signal.

In an implementation form, the group of sub-samplers comprises a number of sub-samplers which are configured to carry out a time interleaved sampling of the analog input signal.

In an implementation form, the divider is configured to further divide its output clock signal into multiple polyphase signals which have a defined phase relationship to the output clock signal; wherein each sub-sampler of the group of sub-samplers is configured to sample the analog input signal using a different polyphase signal.

The polyphaser signals can have the frequency of the output clock signal and can have a fixed phase relation to the output clock signal of a respective divider, i.e., they can be shifted in time relative to the output clock signal. Each polyphase signal can represent one polyphase of the output clock signal.

In an implementation form, the analog-to-digital converter system comprises at least two dividers, each of the at least two dividers configured to generate a respective output clock signal with the second frequency; wherein the analog-to-digital converter system comprises at least two groups of sub-samplers, each group of sub-samplers configured to sample an analog input signal based on a respective output clock signals provided by one of the at least two dividers.

In an implementation form, the group of sub-samplers is configured to start the sampling of the analog input signal based on the synchronization pulse signal.

According to a third aspect, the present disclosure relates to a digital-to-analog converter system comprising the signal processing circuit according to the first aspect of the disclosure.

### BRIEF DESCRIPTION OF THE DRAWINGS

The above-described aspects and implementation forms of the present disclosure will be explained in the following description of specific embodiments in relation to the enclosed drawings, in which:

FIG. 1 shows a schematic diagram of a signal processing circuit according to an embodiment;

FIG. 2 shows a section of the signal processing circuit of FIG. 1 according to an embodiment;

FIGS. 3 and 4 show phase reference and clock signals according to an embodiment.

FIG. 5 shows a phase detector characteristic according to an embodiment; and

FIG. 6 shows an exemplary synchronization in the signal processing circuit.

### DETAILED DESCRIPTIONS OF EMBODIMENTS

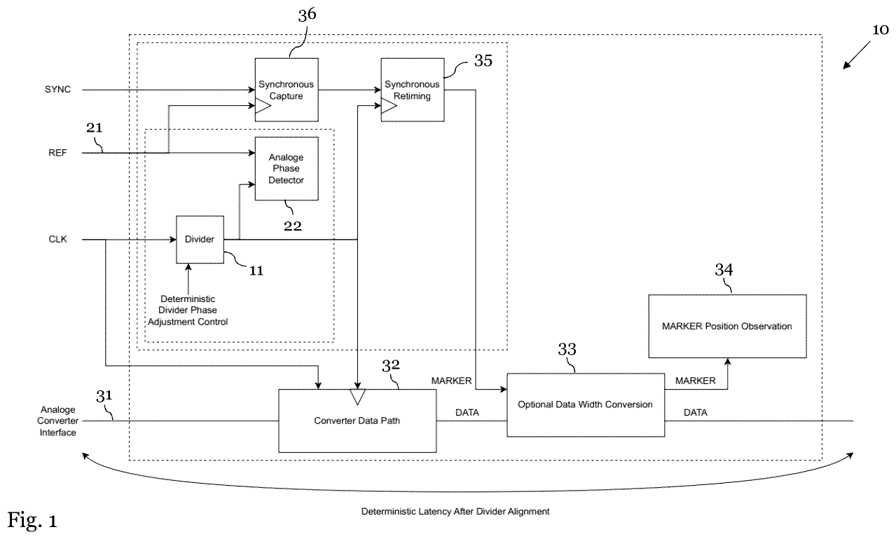

FIG. 1 shows a schematic diagram of a signal processing circuit 10 according to an embodiment. The signal processing circuit 10 comprises: at least one divider 11 configured to receive an input clock signal CLK with a first frequency and to generate an output clock signal with a second frequency which is a fraction of the first frequency; a reference signal unit 21 configured to generate or to receive a phase reference signal; and at least one phase detector 22 configured to detect a phase offset between the output clock signal and the phase reference signal; wherein the at least one divider 11 is configured to shift a phase of its output clock signal in order to adapt the phase offset between its output clock signal and the phase reference signal.

The at least one divider 11 can be configured to shift the phase of its output clock signal by at least one period or half-period of the input clock signal.

Furthermore, the at least one divider 11 can be configured to minimize the phase offset between its output clock signal and the phase reference signal and/or to set the phase offset between its output clock signal and the phase reference signal to be in a determined range.

The signal processing circuit 10 can comprise an input for the input clock signal CLK. Optionally, the signal processing circuit 10 further comprises an input for receiving a synchronization pulse signal SYNC which is synchronous to the phase reference signal. The synchronization pulse signal can be an external signal which is synchronous to the phase reference signal.

The signal processing circuit 10 can be a component of a converter system, such as an analog-to-digital converter (ADC) system or a digital-to-analog converter (DAC) system.

In the following, it is assumed that the signal processing circuit 10 is a component of an exemplary ADC system. The ADC system has a converter interface 31 for receiving analog input signals and a converter data path 32 for converting the input signals to digital output signals.

The converter data path 32 can comprises or be connected to at least one group of sub-samplers which are configured to sample an analog input signal based on the output clock signal provided by the divider 11. The sampled analog input signal can then be converted by a number of ADCs of the system to generate a digital output signal.

For example, the group of sub-samplers comprises sub-samplers which are configured to carry out a time interleaved sampling of the analog input signal.

The divider 11 can be configured to further divide its output clock signal into multiple polyphase signals which have a defined phase relationship to the output clock signal. Each sub-sampler of the group of sub-samplers of an ADC system can be configured to sample the analog input signal using a different polyphase signal provided from the divider 11.

The signal processing circuit 10 can comprises at least two dividers 11, wherein each of the at least two dividers 11 is configured to generate a respective output clock signal with the second frequency, wherein the ADC system can comprise at least two groups of sub-samplers, each group of sub-samplers configured to sample an analog input signal based on a respective output clock signals provided by one of the at least two dividers 11.

The group of sub-samplers can be configured to start the sampling of the analog input signal based on the synchronization pulse signal received at the SYNC input. In this way, a deterministic starting time of a sub-ADC sequence can be provided. For instance, this removes an uncertainty for the sub-ADCs which packet of two (for sub-DACs which of three) sample packets is the first sample packet.

The synchronization pulse signal can be received at a synchronization capture unit 36 of the signal processing circuit 10 and can be forwarded to a synchronization retiming unit 35. The synchronization retiming unit 35 can further be connected to the divider 11.

For instance, the retiming unit 35 can output a number of markers, such as a REF and a SYNC marker. Due to the latency through the ADC system, the REF marker and SYNC marker might not actually mark the sample that corresponds to the REF sampling instant, but mark the sample offset between that physical REF sample and the marked REF sample. The sample offset could be corrected for by delay lines if required.

The markers can be forwarded to an optional data width conversion unit 33 connected to the converter data path 32. A marker position observation unit 34 can further be configured to observe positions of the markers in the data.

The ADC system or more specifically the converter data path 32 of the system can comprise at least one ADC (also referred to as sub-ADCs or sADCs). For instance, the ADC system comprises at least two converter channels, wherein each of the converter channels comprises at least two of the number of sub-samplers and the number of sub-ADCs.

For example, the ADC system comprises a signal processing circuit 10 with a respective divider 11 and a corresponding group of sub-samplers for each converter channel. Each divider 11 can provide phase-differences for the interleaving that is carried out by the pre-samplers (so-called sub-sampling rate or sub-sampling clock). The corresponding converter channel can then receive this pre-sampled analog input signals and convert these signals to digital signals via its sub-ADCs.

The different dividers 11 of different converter channels of the ADC system may initially not be synchronized to each other and may start at different points in times (e.g., depending on the clock cycle times). By adapting the output clock signals of each divider 11 via the comparison with the reference signal, a system-wide synchronization across all converter channels (and associated dividers 11 and groups of pre-samplers) can be realized.

Each divider 11 can be configured to divide its respective output clock signal into multiple polyphase signals, which have a defined phase relation to the output clock signal. The number of sub-samplers associated with said divider 11 can be configured to sample the analog input signal, wherein each sub-sampler uses a different polyphase signal from the divider 11. For instance, each polyphase signal represents a different polyphase of the output clock signal.

For instance, eight sub-samplers of one group of sub-samplers of a converter system may sample an analog input signal at fs/8=2.5 GS/s each, thus a slice generates one sample per fs/8. There can be an offset of 1/fs=50 ps between each polyphase signal for the time interleaved sampling.

The dividers 11 associated to different converter channels may initially start up in different states. As a consequence, the parallel output data per cycles of different ADC channels can start with different analog samples and therefore with different latencies. This asynchronous behavior of different converter channels can be mitigated by adapting the phase offset of the output clock signals via a programmable polyphaser unit.

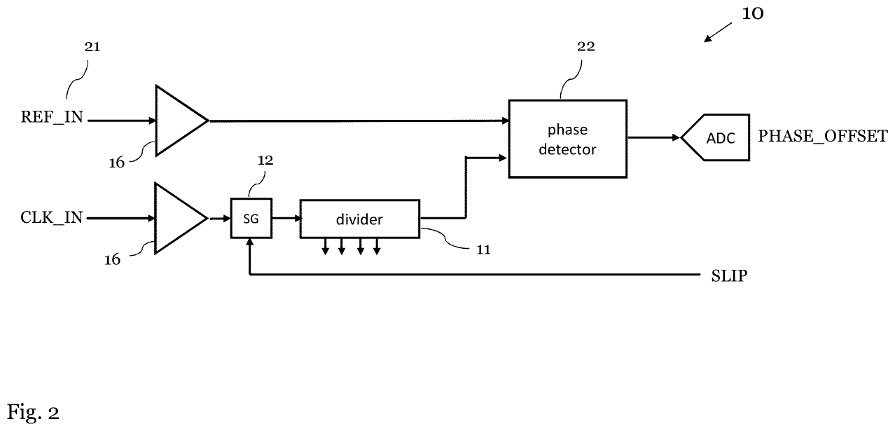

FIG. 2 shows a section of the signal processing circuit 10 of FIG. 1 according to an embodiment. This section comprises the reference signal unit 21 and the phase detector 22.

As shown in FIG. 2, at least one divider 11 can comprise a programmable polyphaser unit 12 which is configured to shift the phase of its output clock signal in order to adapt the phase offset between its output clock signal and the phase reference signal. For instance, the programmable polyphaser unit 12 is a slip gate.

The phase detector 22 can determine the phase offset between the output clock signal of the divider 11 and the phase reference signal and outputs a corresponding phase-offset signal based on which the slip gate 12 controls the divider 11 to shift the phase of the output clock signal.

The dividers 11 of the circuit 10 can be high-performance dividers which generate the output clock signal, wherein the phase of the output clock signal can be adapted by means of the phase detector 22 and the cycle-slipping to generate a deterministic phase relationship between the output clock signals of different dividers.

Hereby, the cycle-slipping carried out by the slip gate 12 can be a “swallowing” or a “slipping” of input clock signal periods respectively pulses (i.e., half-periods) at the divider 11 input (i.e., a “pulse-swallowing”). This is comparable to so-called clock-gating techniques. For instance, the slip gate 12 acts as a “clock cycle swallower” which shifts the output of the 1:4 divider 11 by one polyphase, i.e. one period of fₛ/2.

As shown in FIG. 2, an input CLK_IN for the input clock signal and a further input ADC_IN for the analog input signal can both be connected to a respective buffer 16.

The phase detector 22 can be an analog phase detector. The phase detector 22 can be an integrated element in a chip (e.g., a charge pump). The phase detector 22 can measure analog phase deviations between the reference clock (i.e., the phase reference signal) and the sub-sampler clock (i.e., the output clock signal). The phase detector 22 can ensure that fewer wrong decisions are taken when realigning the output clock phases, even if there is a drift. In other words, the phase detector 22 enhances a tolerance against drift and jitter in the clock signals of the circuit 10. Hereby, realignment can refer to the adjustment of the circuit 10 via software after starting the system.

The reference signal unit 21 can comprises a reference clock configured to generate the phase reference signal based on the input clock signal. For instance, a reference clock is introduced as a synchronization phase reference, which defines one sampling instant in time as the “REF” sample of a data stream.

This reference clock can have steep edges for best jitter performance and should not drift against the sampling clock by more than 1 UI. To achieve this, it can be derived from the sampling clock by division. High performance dividers for these frequencies often only support power-of-2 divider factors. An integrated, analog phase detector in signal processing circuit 10 can allow to measure the phase difference of the internal fₛ/8 clock and the reference clock, which should be

$$\frac{{f}_{s}}{32 \cdot k} ,$$

for instance fₛ/128.

Alternatively, the phase reference signal could also be an external signal which is received by the reference signal unit 21.

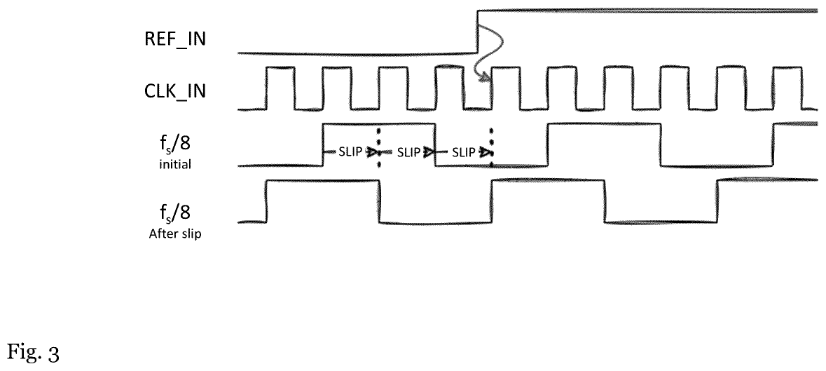

FIG. 3 shows the reference signal and different clock signals of the signal processing circuit 10 according to an embodiment. The two top signals REF_IN and CLK_IN are the phase reference signal and the input clock signal, respectively. Here, one rising edge of REF_IN is shown because the phase reference signal has a much lower frequency than the first frequency of the input clock signal.

The third signal (denoted “fs/8 initial”) is the initial output clock signal of the divider 11 at the second frequency and the fourth signal (denoted “fs/8 after slip”) is the output clock signal after the phase shift due to the slip gate 12. With this phase shift, a rising edge of the output clock signal can be shifted to coincide with the rising edge of the phase reference signal. In other words, the output clock signal can be synchronized to the phase reference signal. This synchronization can be performed for the respective output clock signals of all dividers 11 of the signal processing circuit 10.

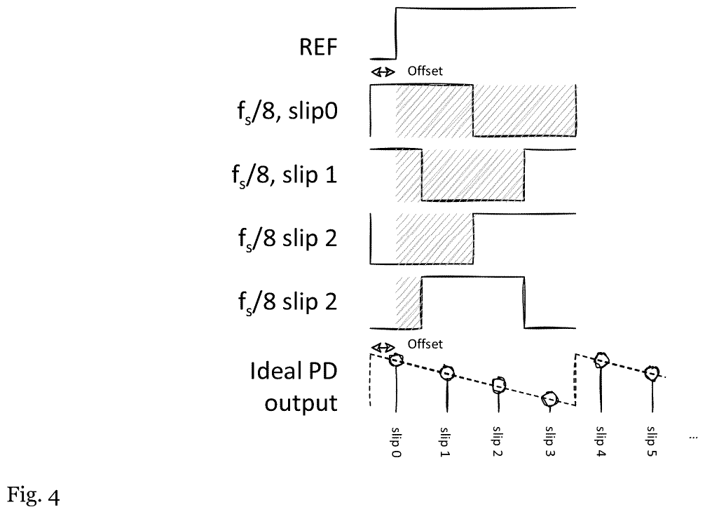

The phase detector 22 can output a phase difference between the rising edge of the reference clock signal and the next rising edge of the output clock signal that follows for different slips (i.e., phase offsets) generated by the slip gate 12. This is shown in FIG. 4, where offset between a phase reference signal REF and output clock signals with different phase shifts (slips) are compared. The phase difference between the rising edge of the phase reference signal REF and the next rising edge of the output clock signal fs/8 is highlighted by the shaded area.

For example, the decision which slip signal in FIG. 4, e.g. fs/8 slip 0 or fs/8 slip 3, has a lower offset to (the rising edge of) the phase reference signal may be narrow and may turn out differently in later realignments. To make this decision, the phase detector 22 essentially measures the shaded area. In another example, two slip signals have the same “distance” to the reference clock and, thus, there is a choice between these signals (non-deterministic). Therefore, the phase detectors 22 can “remember” the phase difference and it is no longer just the minimum phase difference that matters. This ensures that each converter channel makes the same choice among the slips.

The PD (phase difference) output range can be between [0; 360] degrees, where two perfectly aligned clocks would read 0==360 degrees. To eliminate jitter, the result can be averaged. If no jitter or infinite averaging is assumed, the ideal characteristic of the phase detection as a function of the slips is a falling slope (bottom signal denoted as “ideal PD output”).

For instance, the phase detector output can be represented by a falling slope which repeats after its range of

$$8 \cdot \frac{1}{{f}_{s}} .$$

Thereby, one cycle slip can move the output clock signal (and thus the corresponding polyphase signals) by

$$2 \cdot \frac{1}{{f}_{s}} ,$$

such that the measured phase detector value repeats after 4 cycle slips.

Thus, the slip gate 12 can be configured to control the divider to shift a phase of its output clock signal by at least one clock period (or half clock period) of the input clock signal when generating the output clock signal. In this way, the slip gate 12 can carry out a phase alignment between the output clock signal (respectively polyphase signal) and the phase reference signal.

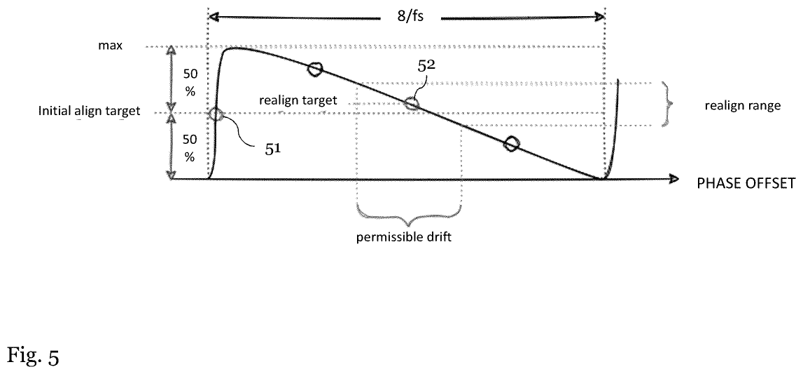

FIG. 5 shows an exemplary phase detector characteristic under the presence of jitter. The jitter can soften the theoretical infinite rising slope of this characteristic. The at least one slip gate 12 can be configured to control the divider to set the phase offset between its output clock signal and the phase reference signal to be in a determined range which is denoted as “realign range” in FIG. 5.

A calibration measurement can be carried out with the circuit 10 to identify the optimal “slip position” (i.e., the optimal phase offset generated by the slip gate 12). For instance, this calibration can be carried out after a start-up of the system: In a first step, all four slip positions can be measured to find the falling slope and rule out points 51 that might lie on the finite rising slope. The initial target 52, before the circuit 10 has been phase calibrated, is the center of the falling slope, as this location has the largest drift margin in both directions. After the circuit 10 has been calibrated, the alignment phase should not change in subsequent realignments, even for small drifts. Therefore, the realign target is to stay closest to the initially measured phase. This provides a window of

$$( CLK ) of \pm \frac{1}{{f}_{s}} ( = \pm 1 sample )$$

permissible drift of the phase reference signal (REF) vs. the input clock signal between alignments.

When the phase offset between the output clock signal and the phase reference signal is minimized for all dividers and thus all converter channels, the polyphase signals will be aligned across all channels. However, there could still be misalignment of sample packets at the interface, which uses a polyphase of fₛ/24 in a DAC system, respectively fₛ/16 in an ADC system.

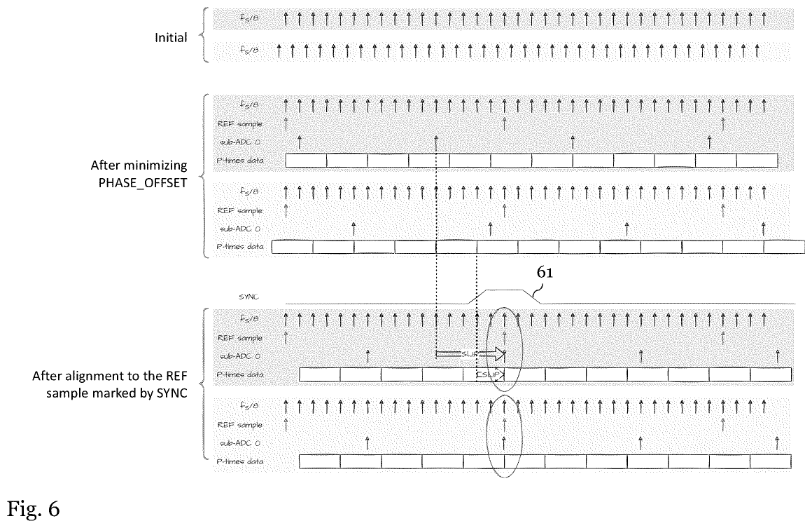

FIG. 6 shows an exemplary synchronization in the signal processing circuit 10 with and without the synchronization pulse signal 61. For instance, the signal processing circuit 10 is used to synchronize sub-ADCs in an ADC system.

The top section of FIG. 6, denoted as “initial”, shows two asynchronous output clock signals fs/8 (e.g., the first polyphase signals of two dividers). These signals could be used by the pre-samplers of different converter channels. The middle section of FIG. 6, denoted as “After minimizing PHASE_OFFSET”, shows the synchronization of these signals via the phase reference signal (here: REF sample). However, the sub-ADCs can still start at different starting times and thus run asynchronous. To mitigate this issue, the synchronization (SYNC) pulse signal 61 can be used, as shown in the bottom section of FIG. 6.

For instance, the external SYNC pulse 61, which is synchronous to REF, can be used to mark which of the REF sampling instants is regarded as the “SYNC” sampling instant that has to be at the top of the 16×- respectively 24×-times parallel output/input.

In the example of FIG. 6, the: sub-ADC 0 (and all other sub-ADCs) has a sampling frequency of fs/80, thus samples again after 10*fs/8 pulses; the REF pulse (i.e., the phase reference signal) allows to synchronize all ADC channels' (e.g., the first fs/8-polyphases). The 1:10 dividers (converting fs/8 to fs/80) could now start arbitrarily with any sub-ADC in that first fs/8 “slice” (e.g., sub-ADC0/8/16/ . . . /72). The synchronization pulse signal 61 can now define a starting point for the dividers of different converter channels.

For instance, the SYNC pulse 61 has a repetition frequency of

$$\frac{{f}_{s}}{32 \cdot k \cdot 3 \cdot 5 \cdot n}$$

(with k>1 being the same k as in the REF frequency and optionally with any integer n>=1) to unambiguously mark the starting point for the alignment of all three (e.g.,

$$\frac{{f}_{s}}{8} - divider ,$$

sub-ADC sequence, 24× parallel data).

The output samples of the ADC system, i.e. the output of the sub-ADCs, can be marked with the following information: which sample corresponds to the rising edge of REF; which sample corresponds to the rising edge of REF with SYNC=1; and which sample corresponds to the sub-ADC 0 in the sub-ADC sequence. This can be realized by a number of markers.

However, to achieve the alignment goals, it is also possible to have an arbitrary number of samples offset between the actual sample and the sample marking, as long as this offset is deterministic and the same for all ADC channels and after all power-ups.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

1. A signal processing circuit, comprising:
at least one divider configured to receive an input clock signal with a first frequency and to generate an output clock signal with a second frequency which is a fraction of the first frequency;
a reference signal unit configured to generate or to receive a phase reference signal;
at least one phase detector configured to detect a phase offset between the output clock signal and the phase reference signal;
wherein the at least one divider is configured to shift a phase of its output clock signal in order to adapt the phase offset between its output clock signal and the phase reference signal.

2. The signal processing circuit of claim 1,
wherein the at least one divider is configured to shift the phase of its output clock signal by at least one period or half-period of the input clock signal.

3. The signal processing circuit of claim 1,
wherein the at least one divider is configured to minimize the phase offset between its output clock signal and the phase reference signal and/or to set the phase offset between its output clock signal and the phase reference signal to be in a determined range.

4. The signal processing circuit of claim 1,
wherein the at least one divider comprises a programmable polyphase unit which is configured to shift the phase of its output clock signal in order to adapt the phase offset between its output clock signal and the phase reference signal.

5. The signal processing circuit of claim 1,
wherein the reference signal unit comprises a reference clock configured to generate the phase reference signal based on the input clock signal.

6. The signal processing circuit of claim 1,
wherein the phase reference signal is an external signal which is received by the reference signal unit.

7. The signal processing circuit of claim 1, further comprising:
an input for receiving a synchronization pulse signal which is synchronous to the phase reference signal.

8. An analog-to-digital converter system, comprising:
a signal processing circuit comprising:
at least one divider configured to receive an input clock signal with a first frequency and to generate an output clock signal with a second frequency which is a fraction of the first frequency;
a reference signal unit configured to generate or to receive a phase reference signal;
at least one phase detector configured to detect a phase offset between the output clock signal and the phase reference signal;
wherein the at least one divider is configured to shift a phase of its output clock signal in order to adapt the phase offset between its output clock signal and the phase reference signal; and
an analog-to-digital converter circuit configured to convert the sampled analog input signal to a digital output signal.

9. The analog-to-digital converter system of claim 8, further comprising:
at least one group of sub-samplers configured to sample an analog input signal based on the output clock signal provided by the divider.

10. The analog-to-digital converter system of claim 9,
wherein the group of sub-samplers comprises a number of sub-samplers which are configured to carry out a time interleaved sampling of the analog input signal.

11. The analog-to-digital converter system of claim 9,
wherein the divider is configured to further divide its output clock signal into multiple polyphase signals which have a defined phase relationship to the output clock signal;
wherein each sub-sampler of the group of sub-samplers is configured to sample the analog input signal using a different polyphase signal.

12. The analog-to-digital converter system of claim 9,
wherein the analog-to-digital converter system comprises at least two dividers, each of the at least two dividers configured to generate a respective output clock signal with the second frequency; and
wherein the analog-to-digital converter system comprises at least two groups of sub-samplers, each group of sub-samplers configured to sample an analog input signal based on a respective output clock signals provided by one of the at least two dividers.

13. The analog-to-digital converter system of claim 7,
wherein the group of sub-samplers is configured to start the sampling of the analog input signal based on the synchronization pulse signal.

14. A digital-to-analog converter system comprising a signal processing circuit, wherein the signal processing circuit comprises:
at least one divider configured to receive an input clock signal with a first frequency and to generate an output clock signal with a second frequency which is a fraction of the first frequency;
a reference signal unit configured to generate or to receive a phase reference signal;
at least one phase detector configured to detect a phase offset between the output clock signal and the phase reference signal;
wherein the at least one divider is configured to shift a phase of its output clock signal in order to adapt the phase offset between its output clock signal and the phase reference signal.

15. The digital-to-analog converter system of claim 14,
wherein the at least one divider is configured to shift the phase of its output clock signal by at least one period or half-period of the input clock signal.

16. The digital-to-analog converter system of claim 14,
wherein the at least one divider is configured to minimize the phase offset between its output clock signal and the phase reference signal and/or to set the phase offset between its output clock signal and the phase reference signal to be in a determined range.

17. The digital-to-analog converter system of claim 14,
wherein the at least one divider comprises a programmable polyphase unit which is configured to shift the phase of its output clock signal in order to adapt the phase offset between its output clock signal and the phase reference signal.

18. The digital-to-analog converter system of claim 14,
wherein the reference signal unit comprises a reference clock configured to generate the phase reference signal based on the input clock signal.

19. The digital-to-analog converter system of claim 14,
wherein the phase reference signal is an external signal which is received by the reference signal unit.

20. The digital-to-analog converter system of claim 1, wherein the signal processing circuit further comprises an input for receiving a synchronization pulse signal which is synchronous to the phase reference signal.
